(19) United States
(12) Patent Application Publication
(10) Pub. No.: US 2010/0102996 A1
(43) Pub. Date: Apr. 29, 2010

(54) Dome array device and a key structure with the dome array device

(76) Inventors: Yui-Chen Huang, Taipei City (TW); Chou-Yang Tsai, Taipei City (TW); Chia-Chun Lin, Taipei City (TW); Kuo-Chih Hsiao, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/289,220

(22) Filed: Oct. 23, 2008

(51) Int. Cl. H03K 17/94

(52) U.S. Cl. 341/22

(57) ABSTRACT

A dome array device is disclosed, which includes a film plate, a plurality of metal flexible plates, and a covering layer. The film plate has a first surface and a second surface. A plurality of flexible press portions protrudes from the film plate. The metal flexible plates are respectively located on the second surface of the flexible press portions of the film plate. The covering layer is formed and covered on the first surface of the film plate. A plurality of plungers that respectively corresponds and locates on the flexible press portions protrudes from the covering layer. A plurality of function portions that is located around the flexible press portions extends and protrudes from the covering layer. Furthermore, a key structure with the dome array device is disclosed, and thereby the operation sensitivity is improved, the total thickness is reduced, and the manufacturing cost is decreased.

### BACKGROUND OF THE INVENTION

1. Field of the Invention

The present invention relates to a dome array device, in particular, the present invention relates to a dome array device with plungers and a key structure with the dome array device.

2. Description of Related Art

Keys act as the main input devices for hand-held electronic devices (such as mobiles phones, PDAs, etc.). Each key on a key module has a label (such as figure, text, character element for the character input way, and/or pictures, etc.) so that the user can confirm and input the exact information. Therefore, for the hand-held electronic devices, keys act as an important interface between the user and the device.

As shown in FIG. 1, that shows a key structure of a hand-held electronic device. The key structure includes a key module 11 and a dome array 12. The key module 11 has a base portion 111 and a key portion 112 located on the base portion 111. The bottom of the base portion 111 protrudes downwards to form a plunger 13. The dome array 12 has a polyethylene terephthalate (PET) film 121. The PET film 121 protrudes to form a press portion 122. The bottom of the press portion 122 has a metal flexible plate 123. The dome array 12 is located above the circuit board (not shown in the figure). The press portion 122 corresponds to a flexible plate switch of the circuit board. Therefore, when the key portion 112 of the key module 11 is pressed, the plunger 13 moves downwards to touch the press portion 122 of the dome array 12 and conduct the metal flexible plate 123 with the flexible plate switch of the circuit board so as to perform the corresponding operation of key input.

Because the hand-held electronic devices are developed by concurrent engineering, each component element of the hand-held electronic devices has its specific range of manufacturing tolerance. Therefore, when the hand-held electronic devices are assembled, assembly displacement may occur. When the key module 11 and the dome array 12 are assembled on the hand-held electronic device, assembly displacement may occur due to the tolerance. The plunger 13 of the key module 11 may not be aligned on top of the press portion 122 of the dome array 12. Thereby the operation sensitivity regarding the key structure of the hand-held electronic devices may be low. Furthermore, because the plunger 13 is connected below the base portion 111, the total thickness of the key module 11 cannot be reduced.

FIG. 2 shows another key structure of a hand-held electronic device. The difference between FIG. 1 and 2, is that the plunger 13′ of FIG. 2 is formed on the press portion 122 of the dome array 12 by an adhesive injecting way so as to improve the problem of the operation sensitivity being low.

The aforementioned adhesive injecting way is a continuously and sequential way of forming a plunger 13′ on a plurality of press portions 122. In other words, the plunger 13′ is formed one after another in a continuous sequential way. By using this way, because the plunger 13′ is formed one by one, the required manufacturing time increases so that the manufacturing cost increases. Therefore, as technology is improved, how to improve the operation sensitivity of a key structure, decrease the total thickness of a hand-held electronic device, decrease the manufacturing cost, and improve the function of a dome array is an issue of concern.

### SUMMARY OF THE INVENTION

One particular aspect of the present invention is to provide a dome array device with plungers and a key structure with the dome array device. It can solve the problem of the operation sensitivity being low resulting from assembly displacement of the key module, and decrease the total thickness of the hand-held electronic device that utilizes the key structure. Further more, the manufacturing time is decreased and the manufacturing cost is lowered.

The dome array device includes a film plate with a first surface and a second surface that are opposite to each other, a plurality of metal flexible plates, and a covering layer. A plurality of flexible press portions protrudes from the film plate. The metal flexible plates are respectively located on the second surface of the flexible press portions of the film plate. The covering layer is formed and covered on the first surface of the film plate. A plurality of plungers protrudes from the covering layer. The plungers respectively correspond and locate on the flexible press portions. A plurality of function portions extends and protrudes from the covering layer. The function portions are located around the flexible press portions.

The present invention also provides a key structure with the dome array device. The key structure with the dome array device includes a key module having a plurality of keys, and a dome array device located below the key module. The dome array device includes a film plate with a first surface and a second surface that are opposite to each other, a plurality of metal flexible plates respectively located on the second surface of the flexible press portions of the film plate, and a covering layer formed and covered on the first surface of the film plate. A plurality of flexible press portions protrudes from the film plate. The first surface is the surface that faces to the key module. The flexible press portions correspond to the keys. A plurality of plungers extends and protrudes from the covering layer. The plungers respectively correspond and locate on the flexible press portions. A plurality of function portions extends and protrudes from the covering layer. The function portions are located around the flexible press portions.

The present invention has the following characteristics. By molding the covering layer on the film plate of the dome array device and forming the plungers and the function portions into one piece, the problem of the operation sensitivity being low resulting from the assembly displacement of the key module is resolved. The thickness of the key module is decreased to reduce the total thickness of the hand-held electronic device. The key structure molding by covering layer can be rapidly manufactured to reduce the manufacturing time and cost. Furthermore, by utilizing the design of the function portions, the function of the dome array device is enhanced.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

The drawings included herein provide a further understanding of the present invention. A brief introduction of the drawings is as follows:

FIG. 1 is a schematic diagram of a key structure of a hand-held electronic device according to a prior art;

FIG. 2 is a schematic diagram of another key structure of a hand-held electronic device according to a prior art;

FIG. 3 is a perspective view of a dome array device of the present invention;

FIG. 4 is an exploded perspective view of the dome array device of the present invention;

FIG. 5 is a cross-sectional diagram of the dome array device of the present invention that shows part of a film plate, a metal flexible plate, and a covering layer; and

FIG. 6 is a cross-sectional diagram of the dome array device and a key module of the present invention that shows part of the assembly result.

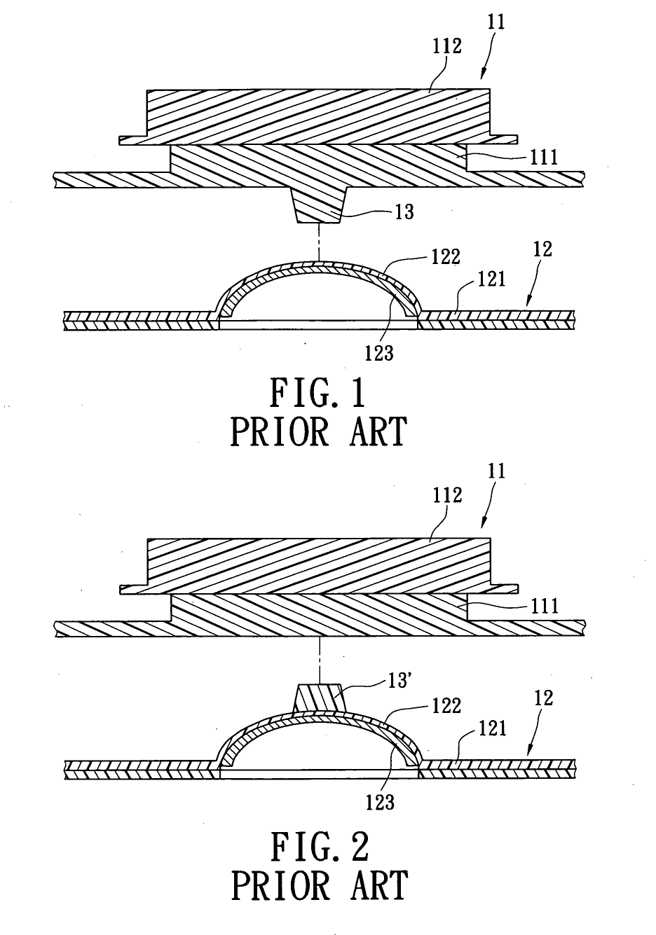

### DETAILED DESCRIPTION OF PREFERRED EMBODIMENTS

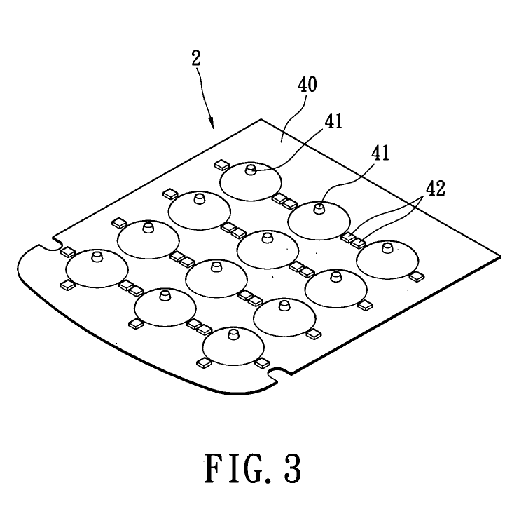

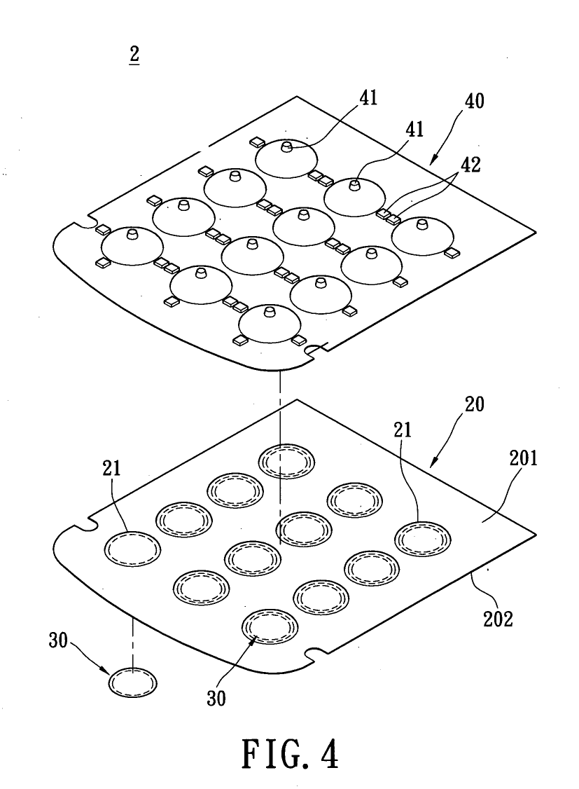

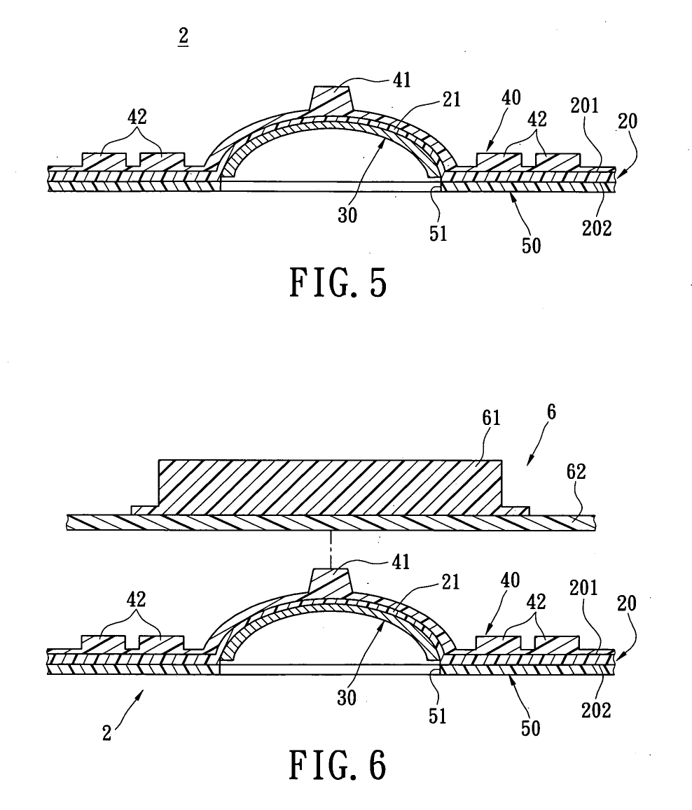

Reference is made to FIGS. 3-5, which show a dome array device 2 of the present invention. The dome array device 2 includes a film plate 20, a plurality of metal flexible plate 30, and a covering layer 40.

The film plate 20 is a polyethylene terephthalate (PET) thin film, and has a first surface 201 and a second surface 202 that are opposite to each other. The first surface 201 is the top surface. The second surface 202 is the bottom surface. A plurality of circular flexible press portions 21 protrudes from the film plate 20.

The metal flexible plates 30 are the electric-conductive component, and are respectively located on the second surface 202 of the flexible press portions 21 of the film plate 20.

The covering layer 40 is formed and covered on the first surface 201 of the film plate 20. The covering layer 40 is formed and covered on the first surface 201 of the film plate 20 into one piece by using the molding method. A plurality of plungers 41 and a plurality of function portions 42 extend and protrude from the covering layer 40. The plungers 41 respectively correspond and locate on the top of the flexible press portions 21. This means that each plunger 41 is located above a flexible press portion 21. The function portions 42 are located around the flexible press portions 21.

The dome array device 2 further includes an adhesive layer 50 that is combined on the second surface 202 of the film plate 20. The adhesive layer 50 has a plurality of through holes 51 that respectively correspond to the flexible press portions 21.

As shown in FIG. 6, the present invention also provides a key structure with the dome array device. The dome array device 2 is located below a key module 6. The key module 6 has a plurality of keys 61 and a base portion 62. The keys 61 are located on the base portion 62. The first surface 201 of the film plate 20 of the dome array device 2 is the surface that faces the key module 6. The flexible press portions 21, the metal flexible plates 30, and the plungers 41 of the covering layer 40 are respectively located below the keys 61 of the key module 6.

The adhesive layer 50 of the dome array device 2 can be pasted onto a circuit board (not shown in the figure) of the hand-held electronic device to position the dome array device 2. The metal flexible plate 30 corresponds to a flexible plate switch of the circuit board. Thereby, the keys 61 of the key module 6 can be pressed onto the plungers 41 of the dome array device 2 so as to press the flexible press portions 21 downwards to conduct the metal flexible plate 30 with the flexible plate switch via the through holes 51 of the adhesive layer 50.

Moreover, the function of the function portion 42 molded on the covering layer 40 may act as a platform structure for pasting (i.e. attaching, where glue or adhesive may be applied), a supporting platform structure, a photo-resist structure, a positioning structure (i.e. for fixing the position), or an optical pattern structure. However, the use of the function portion 42 is not limited thereby. The function portion 42 molded on the covering layer 40 can increase the functions of the dome array device 2. In detail, the function portion 42 is a multi-function structure. A light guide film is usually applied in the key pad structure for improving the quality of light emitted from LEDs in the electronic device. The light guide film is disposed between the key pad and dome array (not shown). Therefore, the function portions 42 are used for increasing the attached areas in order to maintain the leveling and the smooth degree of the light guide film so that the light guide effect can be improved. Moreover, the function portions 42 can be spacers between the light guide film and the dome array in order to define a gap between the light guide film and the dome array. Air in the gap is a medium for transmitting the light emitted from the LEDs in order to increasing the light transmission. On the other hand, the patterns of the light guide are used for scattering the light. However, the covering layer 40 and the function portions 42 can further have patterns thereon for improving the uniformity of the light. Still further, there are some light stoppers for limiting the light leakage inside the inner of the device. Thus, the positions of the function portions 42 can be arranged so that these function portions 42 perform as the stoppers so as to prevent the light leakage from the seam of the casing. Furthermore, the function portions 42 are provided for locating the position of the covering layer 40 in the manufacturing processes.

The present invention molds the covering layer 40 on the film plate 20 of the dome array device 2, and forms the plungers 41 and the function portions 42. By utilizing the design of the plungers 41, the problem of the operation sensitivity being low due to the assembly displacement of the key module 6 can be overcome. Furthermore, the thickness of the key module 6 is reduced to decrease the total thickness of the hand-held electronic device. Moreover, the dome array device 2 of the key structure, formed by molding the covering layer 40 can be rapidly manufactured to reduce the manufacturing cost. By utilizing the design of the function portions 42, the functions of the dome array device 2 can be enhanced.

The description above only illustrates specific embodiments and examples of the present invention. The present invention should therefore cover various modifications and variations made to the herein-described structure and operations of the present invention, provided they fall within the scope of the present invention as defined in the following appended claims.

What is claimed is:

1. A dome array device, comprising:
a film plate having a first surface and a second surface that are opposite to each other, wherein a plurality of flexible press portions protrudes from the film plate;
a plurality of metal flexible plates respectively located on the second surface of the flexible press portions of the film plate; and
a covering layer formed and covered on the first surface of the film plate, wherein a plurality of plungers protrudes from the covering layer, the plungers respectively correspond and locate on the flexible press portions, a plurality of function portions extends and protrudes from the covering layer, and the function portions are located around the flexible press portions.

2. The dome array device as claimed in claim 1, wherein the covering layer is molded on the first surface of the film plate into one piece in a molding way.

3. The dome array device as claimed in claim 1, further comprising an adhesive layer combined on the second surface of the film plate, wherein the adhesive layer has a plurality of through holes corresponding to the flexible press portions.

4. The dome array device as claimed in claim 1, wherein the function portions are used as a platform structure for pasting, a supporting platform structure, a photo-resist structure, or a positioning structure.

5. A key structure with the dome array device, comprising:
a key module having a plurality of keys, and;
a dome array device located below the key module, wherein the dome array device comprises:
a film plate having a first surface and a second surface that are opposite to each other, wherein a plurality of flexible press portions protrudes from the film plate, the first surface is the surface that faces to the key module, and the flexible press portions correspond to the keys;
a plurality of metal flexible plates respectively located on the second surface of the flexible press portions of the film plate; and
a covering layer formed and covered on the first surface of the film plate, wherein a plurality of plungers extends and protrudes from the covering layer, the plungers respectively correspond and locate on the flexible press portions, a plurality of function portions extends and protrudes from the covering layer, and the function portions are located around the flexible press portions.

6. The key structure with the dome array device as claimed in claim 5, wherein the key module further comprises a base portion, and the keys are located on the base portion.

7. The key structure with the dome array device as claimed in claim 5, wherein the covering layer is molded on the first surface of the film plate into one piece in a molding way.

8. The key structure with the dome array device as claimed in claim 5, wherein the dome array device further comprising an adhesive layer combined on the second surface of the film plate, wherein the adhesive layer has a plurality of through holes corresponding to the flexible press portions.

9. The key structure with the dome array device as claimed in claim 5, wherein the function portions are used as a platform structure for pasting, a supporting platform structure, a photo-resist structure, or a positioning structure.
